(19) United States
(12) Patent Application Publication
(10) Pub. No.: US 2019/0219458 A1
(43) Pub. Date: Jul. 18, 2019

(54) Force Measurement Device

(71) Applicant: Torque And More GmbH, Starnberg (DE)

(72) Inventor: Lutz MAY, Starnberg (DE)

(21) Appl. No.: 16/330,282

(22) PCT Filed: Aug. 30, 2017
(86) PCT No.: PCT/EP2017/001029

§ 371 Date: Mar. 4, 2019

(30) Foreign Application Priority Data
Aug. 30, 2016 (EP) 16186445.9

(51) Int. Cl. G01L 1/12; H01F 27/28; G01L 3/10; G01R 33/038

(52) U.S. Cl. CPC G01L 1/125; G01L 1/127; G01L 3/102; G01L 3/105; G01R 33/0385; H01F 27/28

(57) ABSTRACT

A force measurement device includes a flux concentrator with first, second, third, and fourth poles, a magnetic field generating unit generating a magnetic field applied to a test object, and a magnetic field sensing unit with first, second, third, and fourth magnetic field sensors. The flux concentrator is arranged such that each of its poles concentrates the magnetic field. The first, second, third, and fourth poles are arranged such that they form a quadrangle. A first recess is provided such that the first pole is spaced apart from the second and third poles is spaced apart from the fourth pole. A second recess is provided such that the first pole is spaced apart from the third and second poles is spaced apart from the fourth pole. The magnetic field sensors are arranged opposite to each other with the flux concentrator in between and such that the first and third magnetic field sensors both face the first recess and the second and fourth magnetic field sensors both face the second recess. The magnetic field sensing unit provides a signal as an indicator for a force applied to the test object.

### TECHNICAL FIELD

The present invention relates to force measurement, in particular to non-contact force measurement. Particularly, the invention relates to a force measurement device for measuring a force applied to a test object. More particularly, the invention relates to a magnetic based force measurement device for measuring a force applied to a test object.

### BACKGROUND OF THE INVENTION

Force measuring is important for many industrial applications, in particular for arrangements being dynamically impacted by a force. Applied forces may be pressure forces as well as moments like torque and bending impact. An exemplary application for torque is a shaft for a vehicle being arranged between a motor and a wheel. For determining a torque in the shaft, either a particular element needs to be mounted to the shaft, or the shaft needs to be pre-processed, e.g. magnetized. Mounting elements to a shaft may influence the movement of the shaft, pre-processing may be difficult when the shaft is not accessible or cannot be dismounted for pre-processing.

### SUMMARY OF THE INVENTION

It may be seen as an object of the present invention to provide a magnetic principle based mechanical force sensing technology with increased measuring accuracy.

This object is solved by the subject matter of the independent claim, further embodiments are incorporated in the dependent claims and in the following description.

According to a first aspect, a force measurement device for determining a force applied to a test object is provided. The force measurement device comprises a flux concentrator with a first pole, a second pole, a third pole, and a fourth pole, a magnetic field generating unit configured to generate a magnetic field for being applied to a test object, a magnetic field sensing unit with a first magnetic field sensor, a second magnetic field sensor, a third magnetic field sensor, and a fourth magnetic field sensor. The flux concentrator is arranged such that each of its poles concentrates the magnetic field generated by the magnetic field generating unit. The first, second, third, and fourth pole are arranged such that they form a quadrangle. A first recess is provided such that the first pole is spaced apart from the second pole and the third pole is spaced apart from the fourth pole. A second recess is provided such that the first pole is spaced apart from the third pole and the second pole is spaced apart from the fourth pole. The first magnetic field sensor and the third magnetic field sensor are arranged opposite to each other with the flux concentrator in between and such that the first magnetic field sensor and the third magnetic field sensor both face the first recess. The second magnetic field sensor and the fourth magnetic field sensor are arranged opposite to each other with the flux concentrator in between and such that the second magnetic field sensor and the fourth magnetic field sensor both face the second recess. The magnetic field sensing unit is configured to provide a signal as an indicator for a force applied to the test object.

The flux concentrator is shaped like a quadrangle and may be of any quadrangular shape, especially any regular quadrangle like square or rectangle, wherein the poles are arranged at or form the corners of the quadrangle.

The first recess extends from one side to the opposite side of the flux concentrator. The same applies to the second recess. In particular, the first and second recesses are perpendicular with respect to each other. In other words, the recesses extend between the poles and define a gap between the poles.

The first and third magnetic field sensors are arranged such that they detect magnetic field lines evading from the first recess. Similarly, the second and fourth magnetic field sensors are arranged such that they detect magnetic field lines evading from the second recess. Based on the intensity of the magnetic field lines evading from the first and second recess and detected by the magnetic field sensors, the magnetic field sensing unit provides a signal that is indicative for the force applied to a test object.

The magnetic field generating unit generates a magnetic field and the field lines pass through the poles of the flux concentrator. Furthermore, the magnetic field lines passing through one of the poles influence the magnetic field lines passing through the other poles. As a result, the intensity and/or density of the magnetic field lines is higher between the poles, i.e., at the first and second recesses. In addition to the mutual influence of the magnetic field lines passing through the poles of the flux concentrator, the permeability of the test object also influences the magnetic field lines such that the intensity and/or density of the magnetic field lines evading from the first and/or second recess differs. It has been recognized that the permeability of the test object, especially of a surface layer of the test object, changes when a force is applied to the test object. Thus, the altered magnetic field intensity evading from the first and second recess can be used as an indicator for the applied force.

The force measurement device described herein is configured to measure the difference in the permeability at the surface of the test object. The directional permeability inside the material of the test object (especially a ferro-magnetic test object) is subject to the applied mechanical stresses, i.e., the magnetic permeability will increase or decrease in a specific direction when the corresponding mechanical forces act onto the test object. The ability of the test object to take on (absorb) magnetic field lines coming from the outside (like from a magnetic field source or the magnetic field generating unit) that want to travel in a certain direction will be modulated (influenced) by the mechanical stresses that act onto the test object. The force measurement device (may also referred to as sensing element) creates a magnetic field at one magnetic pole (facing the test object) that will be injected into the surface of the test object. Magnetic field sensors (first to fourth magnetic field sensors, S1 to S4) are placed at four strategic locations where the magnetic flux density will be highest when the sensing element is not placed at the test object. When the sensing element is placed on top of a test object (spaced apart at a certain distance from the surface of the test object) then some (or near all) of the magnetic flux generated by the magnetic field generating unit will be “absorbed” by the test object before returning to the other end (the second magnetic pole) of the magnetic field generating unit. When the directional sensitive permeability of the test object is changing (meaning that in a first axis the permeability will increase while in another direction or second axis, e.g., orthogonal to the first axis, it will then decrease), the magnetic field sensors will pick-up the magnetic flux that has not been absorbed by the test object. The signal amplitude differences between the first pair of sensors (first and third magnetic field sensors) versus the second pair of sensors (second and fourth sensors) indicates that the permeability in the surface of the test object has changed in a specific direction.

According to an embodiment, the first, second, third, and fourth pole are arranged such that they form a square.

Thus, the distance between one pole and each of its two direct neighbors along a circumference of the square is equal.

According to a further embodiment, the first, second, third, and fourth pole extend in the same direction and are parallel to each other.

Especially, the poles all extend towards a surface of the test object such that the magnetic field lines are directed to intrude or enter the test object.

According to a further embodiment, the first recess and the second recess extend over an entire width of the flux concentrator.

Thus, there is a direct line of sight between the magnetic field sensors opposite to each other. The first and second recesses may be referred to as a groove having a depth in a direction of extension of the poles and a width from one lateral side of the flux concentrator to an opposite lateral side. In one embodiment, each of the first and second recesses has a uniform width and uniform depth.

According to a further embodiment, the first recess and the second recess intersect at an angle between 85° and 95°.

According to a further embodiment, the first recess and the second recess extend over an entire width of the flux concentrator, i.e., from one lateral side of the flux concentrator to an opposite lateral side.

According to a further embodiment, a distance between two opposite magnetic field sensors is larger than a width of the flux concentrator.

Thus, the magnetic field sensors are spaced apart at a certain distance from the flux concentrator and the respective poles.

According to a further embodiment, two opposite magnetic field sensors are equally spaced apart from a circumference of the flux concentrator, such that a lateral offset between each of the two opposite magnetic field sensors and the circumference is equal.

In other words, the flux concentrator is centered between two opposite magnetic field sensors.

According to a further embodiment, the flux concentrator comprises a base plate and each one of the poles is arranged at the base plate. Thus, there is a magnetic connection between the poles of the flux concentrator.

According to a further embodiment, the flux concentrator is formed in one piece. For example, the flux concentrator is made of a single block. In one example, the flux concentrator is a monobloc concentrator.

According to a further embodiment, the magnetic field sensors are arranged such that a sensing direction of the magnetic field sensors is directed towards the first or second recess.

The magnetic field sensors are arranged such that they detect the magnetic field lines, i.e., their intensity and/or density, evading from one of the recesses. Thus, the force measurement device described in this embodiment focuses on the impact of the test object's permeability on the magnetic field lines evading from the recesses of the flux concentrator instead of measuring the direction or intensity of the magnetic field lines evading from the test object.

According to a further embodiment, the magnetic field sensors are arranged such that a sensing direction of the magnetic field sensors is parallel to the poles of the flux concentrators.

In this embodiment, the magnetic field sensors detect the magnetic field lines evading from the test object's surface. However, the magnetic field sensors are located opposite to one of the recesses. The magnetic field lines evading from the recesses also intrude the test object and return to the magnetic pole. Therefore, also those magnetic field lines are impacted by the changed permeability of (a surface layer of) the test object due to an applied force.

According to a further embodiment, the flux concentrator is made of ferrite or ferromagnetic material.

According to a further embodiment, the magnetic field generating unit comprises a first coil that is wound around all of the first, second, third, and fourth pole along a circumference of the flux concentrator, and the first coil is connected to a power source that provides an electric signal to the first coil such that the first coil generates a magnetic field.

This magnetic field is concentrated by the flux concentrator and the poles direct the magnetic field lines towards the surface of the test object.

According to a further embodiment, the force measurement device further comprises a first adder, a second adder, and a signal processing unit. The first magnetic field sensor and the third magnetic field sensor are connected to the first adder so that the signal provided by these sensors are added. The second magnetic field sensor and the fourth magnetic field sensor are connected to the second adder so that the signal provided by these sensors are added. The signal processing unit is connected to the first adder and to the second adder and configured to process the signals provided by the first and the second adder in order to determine a force applied to a test object.

### BRIEF DESCRIPTION OF THE DRAWINGS

In the following for further illustration and to provide a better understanding of the present invention exemplary embodiments are described in more detail with reference to the enclosed drawings, in which

FIG. 1 schematically shows a permanent magnet and a magnetic field applied to a test object in a side view and in a top view,

FIG. 2 schematically shows two permanent magnets and a resulting magnetic field applied to a test object in a side view and in a top view,

FIG. 3 schematically shows a force measurement device according to an exemplary embodiment of the invention in a top view and in a side view,

FIG. 4 schematically shows a force measurement device according to an exemplary embodiment of the invention in a top view,

FIG. 5 schematically shows a force measurement device according to an exemplary embodiment of the invention in a top view and in a side view,

FIG. 6 schematically shows a force measurement device according to an exemplary embodiment of the invention in a top view and in a side view,

FIG. 7 schematically shows a force measurement device according to an exemplary embodiment of the invention in a top view and in a side view,

FIG. 8 schematically shows a force measurement device according to an exemplary embodiment of the invention in top views of three different scenarios,

FIG. 9 schematically shows a force measurement device according to an exemplary embodiment of the invention in a top view,

FIG. 10 schematically shows a flux concentrator of a force measurement device according to an exemplary embodiment of the invention,

FIG. 11 schematically shows a force measurement device according to an exemplary embodiment of the invention placed at a test object for measuring applied forces,

FIG. 12 schematically shows a force measurement device according to an exemplary embodiment of the invention placed at a test object for measuring applied forces,

FIG. 13 schematically shows a force measurement device according to an exemplary embodiment of the invention,

FIG. 14 schematically shows a force measurement device according to an exemplary embodiment of the invention,

FIG. 15 schematically shows a force measurement device according to an exemplary embodiment of the invention,

FIG. 16 schematically shows a flux concentrator for a force measurement device according to an exemplary embodiment of the invention.

### DETAILED DESCRIPTION OF EXEMPLARY EMBODIMENTS

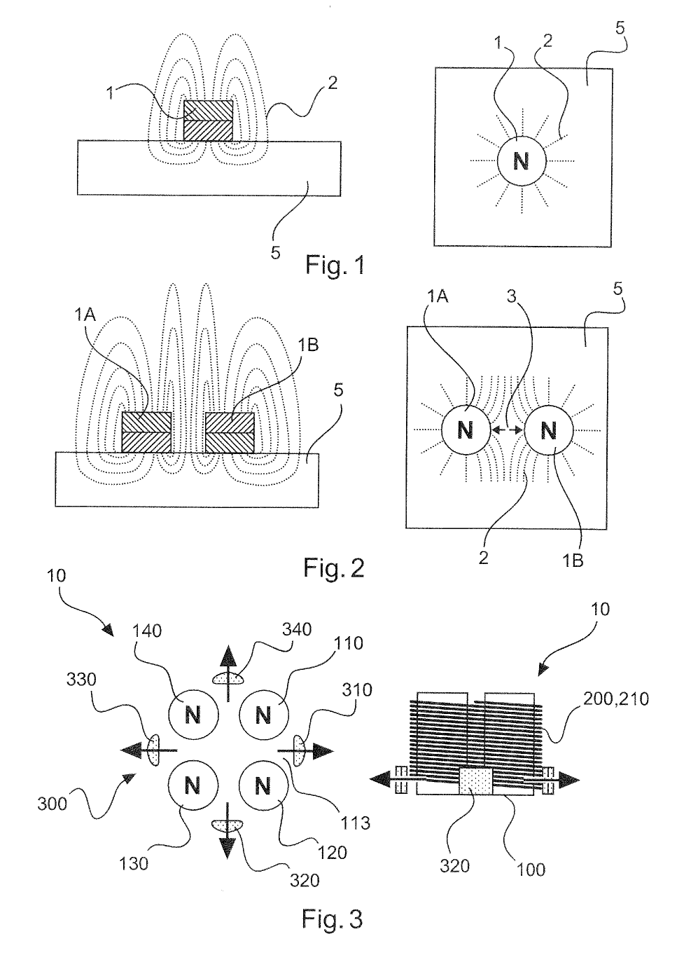

FIG. 1 shows a permanent magnet 1 located close to a test object 5 and the magnetic field 2. On the left, a side view is shown and, on the right, a top view is shown, each schematically indicating the permanent magnet and the magnetic field lines running from one pole of the magnet to the other pole.

It can be seen that the magnetic field lines of the magnetic field 2 run differently in the air surrounding the permanent magnet 1 and in the test object 5 (in particular a ferro-magnetic test object). It has been recognized that a specific part of the magnetic field lines run through a surface layer of the test object. If the permeability of the test object 5 changes due to an applied force (for example torque or bending), this also influences the magnetic field lines of the magnetic field so that a conclusion can be drawn from the measured magnetic field to the intensity of the applied forces. However, FIG. 1 shows the unloaded case.

When placing a symmetrical shaped permanent magnet onto a ferro magnetic object, under normal circumstances, the magnetic field that is running beneath the permanent magnet inside the surface of the test object and the magnetic field lines are evenly distributed.

FIG. 2 shows a schematic representation similar to that of FIG. 1. While in FIG. 1 only one permanent magnet is shown, FIG. 2 shows two permanent magnets 1A, 1B placed close to each other with a gap 3 in between. In the side view on the left and also in the top view of the right it can be seen that the magnetic fields of the permanent magnets 1A, 1B influence each other such that the density of the magnetic field lines is higher close to gap 3.

When placing two identical symmetrically shaped permanent magnets side-by-side and close to each other onto a ferro magnetic object, then the repellent forces of the flux lines from the two magnets 1A, 1B create two concentrated areas of magnetic field distribution (above and below the gap 3 shown in the top view of FIG. 2).

FIG. 3 shows a force measurement device 10. On the left, a top view (or bottom view) is shown and on the right, a side view of device 10 is shown. In the top view, it can be seen that four poles 110, 120, 130, 140 are arranged at the corners of a square such that a horizontal gap 113 and a vertical gap is provided. These gaps are referred to as the first and second recess.

The magnetic field sensing unit 300 comprises four magnetic field sensors 310, 320, 330, 340. The first and the third magnetic field sensors 310, 330 are arranged opposite to each other with the horizontal gap in between and the second and fourth magnetic field sensors 320, 340 are arranged opposite to each other with the vertical gap in between. Thus, the magnetic field sensors detect the magnetic field intensity evading from the respective gap, as indicated by the arrows. As can be seen in the side view of the force measuring device 10, the magnetic field sensors are arranged on a level with the end faces of the poles, wherein the end faces are directed towards the test object. Thus, the magnetic field sensors detect a maximum deflection of the magnetic field lines.

In the side view of FIG. 3, it can also be seen that the magnetic field generating unit 200 comprises a coil 210 that is wound around the poles of the flux concentrator.

Basically, the force measurement device 10 consists of a sensing element and the sensor electronics (not shown in FIG. 3, see FIG. 13 to FIG. 15). Both are connected to each other by a number of wires. The sensing element is placed onto the surface (with or without an air gap of a few millimeters) of a ferro magnetic test object from where the measurements will be taken. The test object can be a solid or hollow beam or shaft. The mechanical force measurements are not sensitive to lateral or rotational movements of the test object, as long as the distance (air gap) is kept the same.

The values of the magnetic flux concentrations evading from the horizontal and vertical gap can be measured using magnetic field sensors (MFS) like hall effect sensors or flux gate devices (for example). In FIG. 3, the hall effect sensors or MFS sensors are arranged upright and their measurement direction is indicated by the arrows. In this embodiment, by summing up the signals of opposite placed MFS devices will compensate for the unwanted effects of magnetic and electromagnetic uniform stray fields interfering with the magnetic field generated by the magnetic field generating unit.

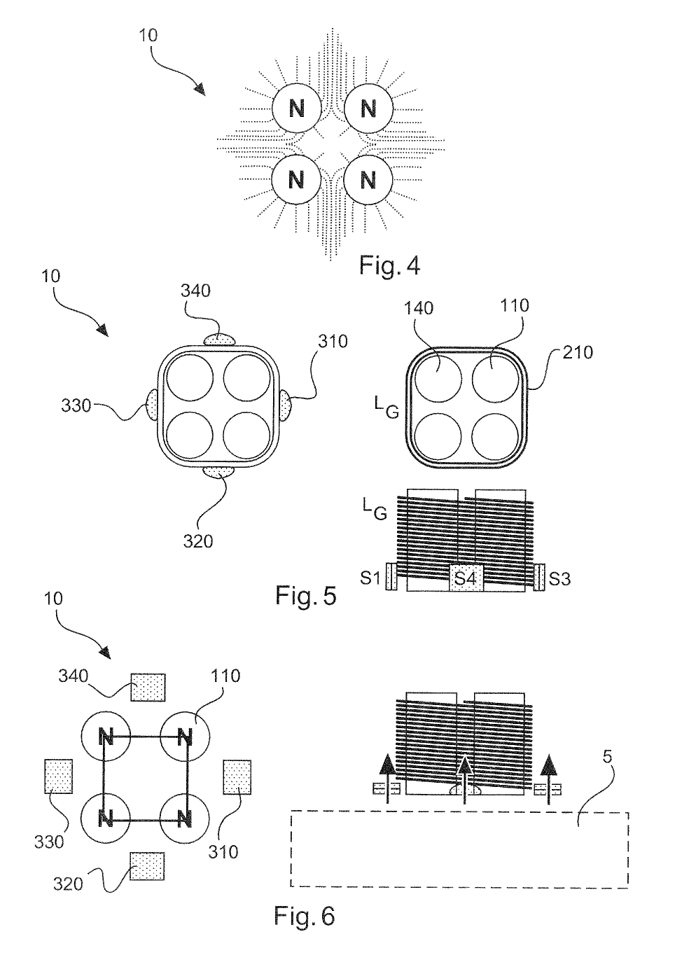

FIG. 4 shows in more detail the magnetic field line distribution for a force measurement device 10. It can be seen that the field lines evading from one of the gaps or recesses are denser.

Generally, placing four identically sized and symmetrically shaped magnets in a square shape side-by-side onto a ferro magnetic object (unloaded, i.e., no mechanical forces are applied to the object) will result in an increased magnetic flux concentration in four areas as shown in FIG. 4. The lines represent the density of the magnetic flux lines running inside the ferro magnetic object.

FIG. 5 shows top views and a side view of a force measurement device 10. In order to generate a magnetic field, a coil 210 (also referred to as L_{G}) is wound around all four poles. Magnetic field sensors 310, 320, 330, 340 (may be referred to as S1, S2, S3, S4) are place opposite to the recesses between the poles.

Mechanical stress or load applied to the test object will influence the permeability and, therefore, the magnetic field. For example, the more mechanical stress is travelling through the surface of the test object, the smaller the returning sensor signal will be. However, an applied force will influence the magnetic field evading from the two recesses in a different manner as will be explained in more detail below.

FIG. 6 shows a force measurement device 10 similar to that one shown in FIG. 3. However, the magnetic field sensors 310, 320, 330, 340 are arranged such that they detect the magnetic field lines running out of the test object 5, see arrows in the side view on the right. Furthermore, in FIG. 6 it is shown that the poles of the flux concentrator are arranged like a square.

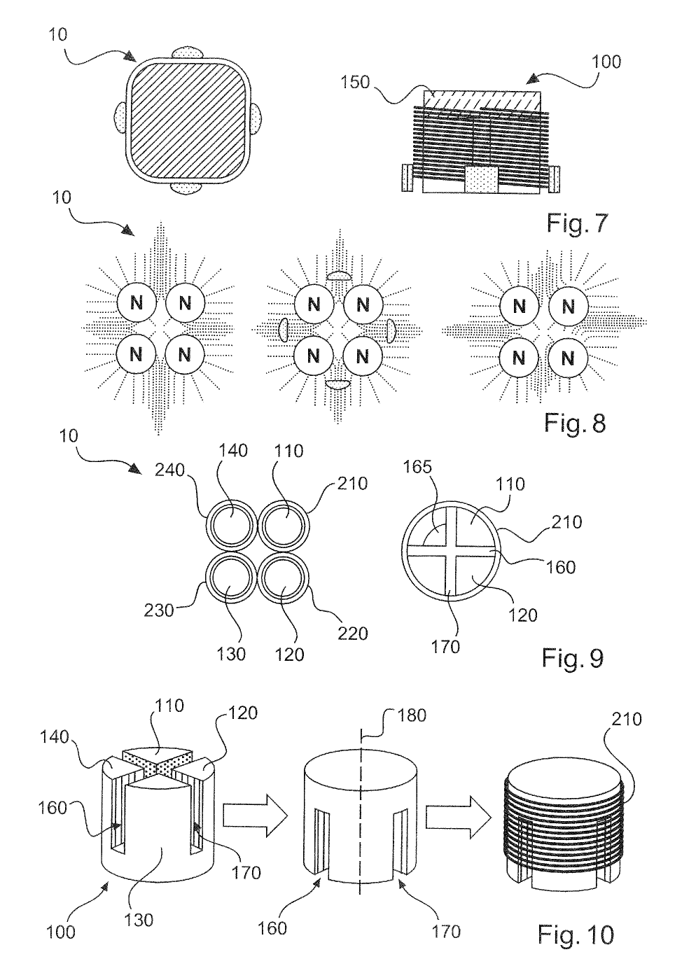

FIG. 7 shows a force measuring device 10 with a flux concentrator 100 having a base plate 150 interconnecting all four poles. Preferably, coil 210 is wound around the poles along a majority of the height of the poles, i.e., substantially from the end faces of the poles to the base plate. However, an end section of the poles may remain free without being surrounded by coil 210.

Terminating the four poles of the flux concentrator with a base plate may increase the signal strength of the force measuring device. The base plate is optional and may allow to measure smaller signals and may improve the signal-to-noise ratio. The flux lines concentration of the flux lines that are travelling through the test object are manipulated or influenced by the mechanical stresses that are applied to the test object. The mechanical stresses act on the magnetic domains (inside the test object) and have an impact on the directional permeability of the test object, especially of the surface of the test object. Examples thereof are shown in FIG. 8.

FIG. 8 exemplarily shows the effect of mechanical forces applied to the test object to the magnetic field lines evading from the recesses of the flux concentrator.

Depending on the mechanical forces applied to the test object, the concentrated magnetic field exiting the four flux zones will be differently strong or intense. The picture in the middle shows also the placement of the four magnetic field sensors with respect to the poles of the flux concentrator.

The left picture schematically shows the effect of a positive torque (torque in a first direction) applied to the test object. The magnetic field lines evading from the vertical gap are more intense than the magnetic field lines evading from the horizontal gap.

The right picture schematically shows the effect of a negative torque (torque in a second direction opposite to the first direction mentioned above with reference to the left picture) applied to the test object. On the right, the magnetic field lines are converse to those shown on the left. Magnetic field lines evading from the vertical gap are less intense than the magnetic field lines evading from the horizontal gap.

The middle picture shows the unloaded case with the magnetic field lines evading from the horizontal gap being equally intense as those evading from the vertical gap.

FIG. 9 shows two possible basic design options of a flux concentrator 100 for a force measuring device 10. Each of these design options has four poles 110, 120, 130, 140. In one option (on the left), four cylindrical poles are provided, each having an individual inductors (coils) placed onto them. The coils can be connected in series with each other or parallel to each other. In another option (on the right) is an alternative shape for the flux concentrator which may provide a larger differential signal. The design option shown on the right is described in more detail with reference to FIG. 10. An angle 165 between the first recess 160 and the second recess 170 may be between 85° and 95°, preferably 90°. It is noted that either of these design options can be used with the force measuring device described herein.

FIG. 10 schematically shows isometric views of a flux concentrator 100 at different manufacturing stages. The flux concentrator is made of a symmetrically shaped cylinder made of high permeability material and by providing two straight cuts (first recess 160 and second recess 170) along a longitudinal axis 180 of the cylinder. The recesses 160, 170 split up the cylinder into four poles that are connected to a base plate (that part of the cylinder not being cut). In one step, a coil 210 is wound around the flux concentrator 100.

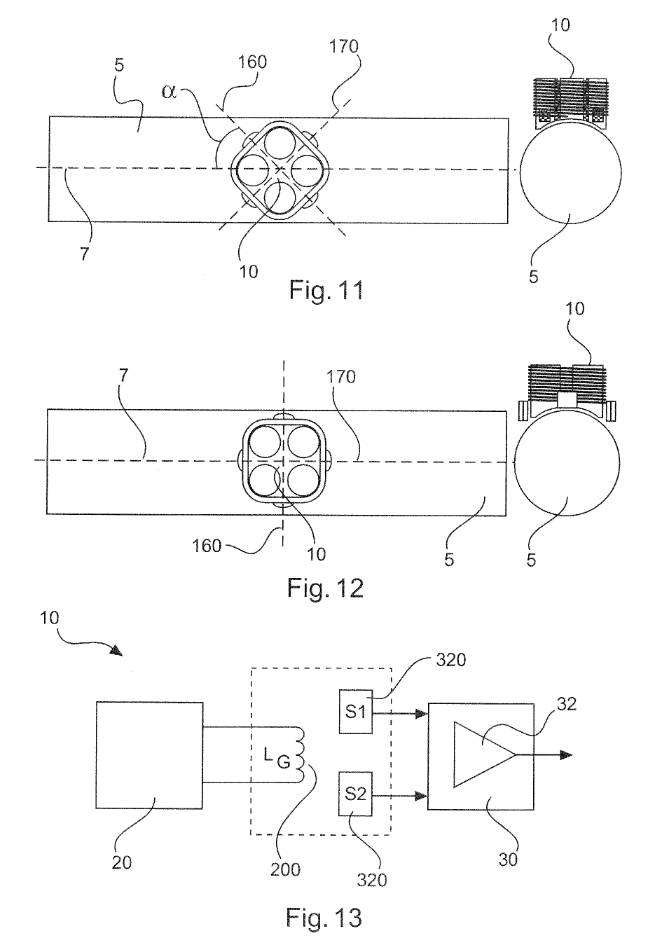

FIG. 11 and FIG. 12 show placement options of the force measuring device 10 with respect to the test object 5. Depending on the placement, bending forces (FIG. 12) or torque forces (FIG. 11) will be measured.

In FIG. 11, the flux concentrator of the force measuring device 10 is arranged with respect to the test object 5 such that the first recess 160 and the second recess 170 are inclined with respect to the longitudinal central axis 7 of the test object. This enables measuring torque forces applied to the test object in both directions (clockwise and counter clockwise). The first recess 160 preferably intersects the longitudinal axis 7 at an angle α between 40° and 50°, more preferably 45°.

Generally, the second recess 170 and the first recess 160 intersect each other at an angle between 85° and 95°, preferably 90°.

In the embodiment of FIG. 11 and FIG. 12, the front face of the flux concentrator (bottom face, end faces of the poles) may have a curved or concave shape (see picture on the right, respectively) so that there is an equal distance between the surface of the test object 5 and the end faces of the poles which may improve the signal to noise ratio.

In FIG. 12, one of the recesses (in this case, the second recess 170) is parallel to the longitudinal axis 7 of the test object 5. This enables to measure bending forces applied to the test object. In the embodiment of FIG. 12, the magnetic field sensors are arranged at different levels with respect to each other due to the concave shape of the flux concentrator.

FIG. 13 shows a schematic illustration of a force measuring device 10 comprising a power source 20, a magnetic field generating unit 200, a magnetic field sensing unit with two magnetic field sensors 310, 320, and a signal processing unit 30 with an amplifier 32.

The magnetic field generator may be driven by a DC (direct current) or by an AC (alternating current) signal type. In one embodiments, the force measuring device will be driven by a DC (direct current) and only two magnetic field sensors (from the possible four MFS) will be used.

While this circuit is straight forward and very simple, the output signal may be sensitive to certain type of magnetic and electromagnetic interferences.

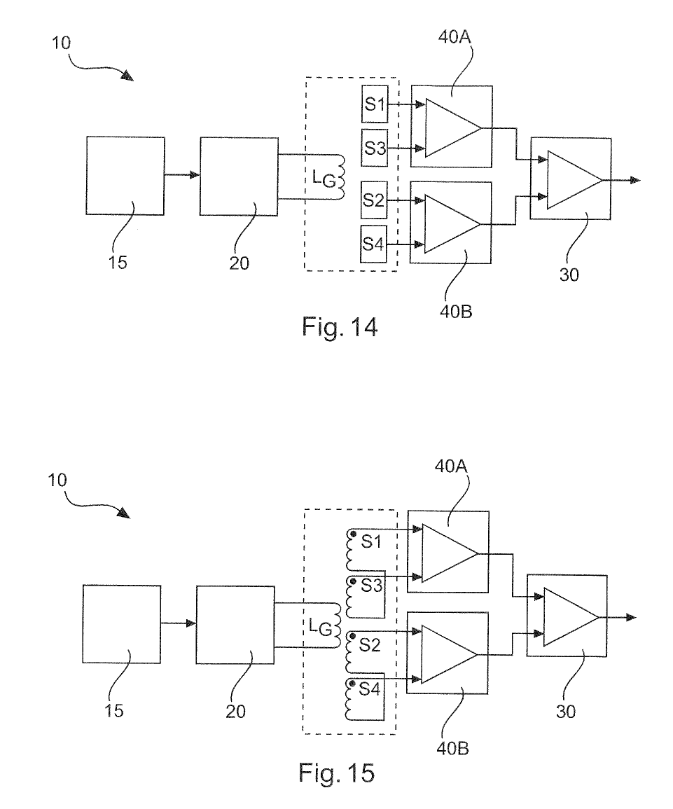

With reference to FIG. 13, FIG. 14 describes an alternative design of the force measuring device 10. The force measuring device 10 further comprises an oscillator 15. There are two pairs of magnetic field sensors (S1 and S3 on the one hand and S2 and S4 on the other hand) each connected to an adder 40A, 40B so that the sum of the signal of each pair of sensors is provided to the signal processing unit 30.

In this embodiment, the electronics is based on a signal amplitude demodulation. The signal output will be of the same frequency as generated by the oscillator and the inductor L_{G}. When no mechanical forces are applied to the ferro magnetic test object then there will be no alternating signal at the sensor output. The more mechanical forces (of the correct type in correspondence with the orientation of the force measuring device with respect to the test object, see FIG. 11 and FIG. 12: either torque or bending) will be applied to the test object the larger the alternating signal will be at the sensor output.

When applying an AC signal of a certain frequency and when using all four magnetic field sensors, then the output signal of the force measuring device 10 is compensated for unwanted magnetic interferences like the earth magnetic field, uniform magnetic stray fields, and electromagnetic interference (EMI) caused by solenoid powered actuators, for example.

The signals of the opposite placed magnetic field sensors are summed-up first as this will eliminate uniform magnetic interferences (as caused by the earth magnetic field or by active solenoids and electric motors, for example). The signals from the two adders 40A, 40B will then be passed-on to a signal processing unit 30 with a differential amplifier. The output of the differential amplifier is then a representation of the mechanical stresses applied to the test object.

FIG. 15 shows a further embodiment of the force measuring device 10. When using an alternating signal (AC) to drive the magnetic field generator, then it is possible to use inductors (coils) as magnetic field sensors S1 to S4 to measure the intensity of the magnetic field. To achieve best possible compensation for unwanted EMI (electromagnetic interferences) effects, the signals measured by the coils S1 and S3 may be subtracted from each other, and so from the coils S2 and S4. When the coils are identical (same impedance and same dimensions) then the subtraction can be achieved by placing the two coils in series (anti-serial) to each other.

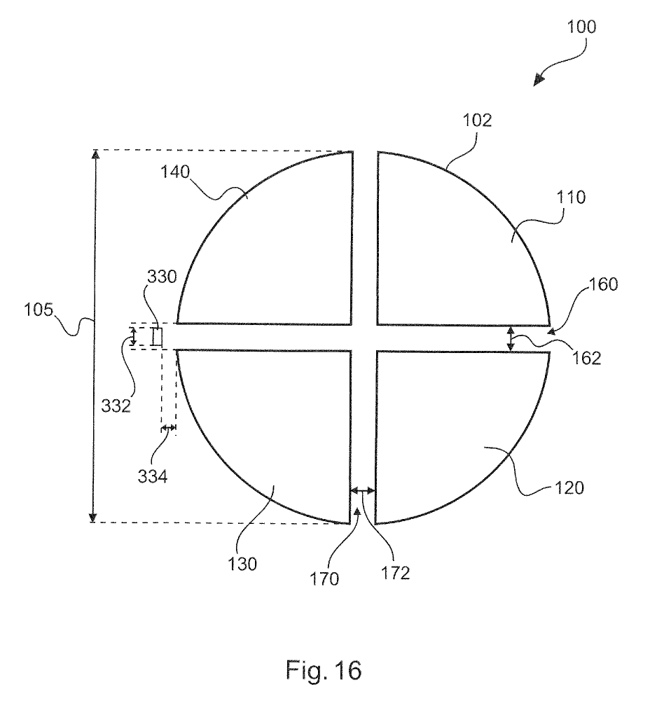

FIG. 16 shows a bottom view of a flux concentrator 100 for a force measuring device described herein. The flux concentrator 100 has four poles 110, 120, 130, 140 and two recesses 160, 170 split up these poles. The recesses are arranged cross-like and intersect each other preferably at 90°. The flux concentrator 100 has a width 105 (that substantially corresponds to the diameter of the cylinder referred to in the description of FIG. 10) that corresponds to the lateral extent of the recesses 160, 170. The flux concentrator 100 has a circumference for receiving a winding or coil, so that the coil is positioned at the outer surface of the poles for inducing a magnetic field into the poles of the flux concentrator. The diameter (width 105) of the flux concentrator 100 may be between 18 mm and 30 mm or even more. The coil 210 that is used as a magnetic field generating unit may be wound around the poles of the flux concentrator 100 such that it has one or more winding layers and the magnetic field sensors may be arranged as close as possible to the outer surface of the coil 210.

Each of the first and second recess 160, 170 has a width 162, 172 which is substantially uniform from one side to the opposite side and also from the bottom to the top, i.e., from the end faces of the poles to the base plate. The width 162, 172 may be between 0.5 mm and 1 mm, for example.

For the sake of brevity, only one magnetic field sensor 330 is shown. However, it is noted that the remarks relating thereto apply in a similar manner to the remaining sensors (not shown). The magnetic field sensor 330 has a width 332 (effective sensing width) that is smaller or equal to the width 162 of the recess it faces. This applies independently of the orientation of the sensor 330, i.e., be it arranged such that it faces the surface of the test object or the recess, see FIG. 3 and FIG. 6.

A lateral spacing 334 between the sensor 330 and the circumference of the flux concentrator (actually the outer surface of the coil wound around the flux concentrator) is provided. The lateral spacing may be 0 (that is, the sensor is arranged at the coil wound around the flux concentrator) or larger (e.g., between 0.2 mm and 1 mm).

The force measuring device 10 described herein is a non-contact mechanical force sensor responding to mechanical stresses in ferro-magnetic test objects. It can be used to measure any mechanical forces like torque, bending, or axial load. The force measuring device may rest upon the surface of the test object or there can be a gap of several millimeters. The device is insensitive to rotational or lateral movement of the test object and also insensitive to oil, water, dust, and other substances that may surround the test object of the force measuring device.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing the exemplary embodiment or exemplary embodiments. It should be understood that various changes can be made in the function and arrangement of elements without departing from the scope of the disclosure as set forth in the appended claims and the legal equivalents thereof.

### LIST OF REFERENCE SIGNS

1 permanent magnet
2 magnetic field
3 gap
5 test object
7 longitudinal central axis
10 force measurement device
15 oscillator
20 power source
30 signal processing unit
32 amplifier
40A first adder
40B second adder
100 flux concentrator
102 circumference
105 width
110 first pole
113 gap
120 second pole
130 third pole
140 fourth pole
150 base plate
160 first recess
162 width
165 angle between first and second recess
170 second recess
172 width
180 axis
200 magnetic held generating unit
210 first coil
220 second coil
230 third coil
240 fourth coil
300 magnetic field sensing unit
310 first magnetic field sensor
320 second magnetic field sensor
330 third magnetic field sensor
332 width
334 lateral spacing
340 fourth magnetic field sensor

1-15. (canceled)

16. A force measurement device for determining a force applied to a test object, comprising:
a flux concentrator with a first pole, a second pole, a third pole, and a fourth pole;
a magnetic field generating unit configured to generate a magnetic field, the magnetic field being applied to a test object; and
a magnetic field sensing unit with a first magnetic field sensor, a second magnetic field sensor, a third magnetic field sensor, and a fourth magnetic field sensor;
wherein the flux concentrator is arranged such that each of the first, second, third and fourth poles concentrates the magnetic field;
wherein the first, second, third, and fourth poles are arranged such that they faun a quadrangle;
wherein a first recess is provided such that the first pole is spaced apart from the second pole and the third pole is spaced apart from the fourth pole;
wherein a second recess is provided such that the first pole is spaced apart from the third pole and the second pole is spaced apart from the fourth pole;
wherein the first magnetic field sensor and the third magnetic field sensor are arranged opposite to each other with the flux concentrator in between and such that the first magnetic field sensor and the third magnetic field sensor both face the first recess;
wherein the second magnetic field sensor and the fourth magnetic field sensor are arranged opposite to each other with the flux concentrator in between and such that the second magnetic field sensor and the fourth magnetic field sensor both face the second recess; and
wherein the magnetic field sensing unit is configured to provide a signal as an indicator for a force applied to the test object.

17. The force measurement device of claim 16, wherein the first, second, third, and fourth poles are arranged such that they form a square.

18. The force measurement device of claim 16, wherein the first, second, third, and fourth poles extend in the same direction and are parallel to each other.

19. The force measurement device of claim 16, wherein the first recess and the second recess extend over an entire width of the flux concentrator.

20. The force measurement device of claim 19, wherein the first recess and the second recess intersect at an angle between 85° and 95°.

21. The force measurement device of claim 16, wherein the first recess and the second recess extend over an entire width of the flux concentrator.

22. The force measurement device of claim 16, wherein a distance between two opposite magnetic field sensors is larger than a width of the flux concentrator.

23. The force measurement device of claim 16, wherein two opposite magnetic field sensors are equally spaced apart from a circumference of the flux concentrator, such that a lateral offset between each of the two opposite magnetic field sensors and the circumference is equal.

24. The force measurement device of claim 16, wherein the flux concentrator comprises a base plate and each one of the first, second, third and fourth poles is arranged at the base plate.

25. The force measurement device of claim 24, wherein the flux concentrator is formed in one piece.

26. The force measurement device of claim 16, wherein the magnetic field sensors are arranged such that a sensing direction of the magnetic field sensors is directed towards the first or second recesses.

27. The force measurement device of claim 16, wherein the magnetic field sensors are arranged such that a sensing direction of the magnetic field sensors is parallel to the first, second third and fourth poles.

28. The force measurement device of claim 16, wherein the flux concentrator is made of ferrite or ferromagnetic material.

29. The force measurement device of claim 16, wherein the magnetic field generating unit comprises a first coil that is wound around all of the first, second, third, and fourth poles along a circumference of the flux concentrator; and
wherein the first coil is connected to a power source that provides an electric signal to the first coil such that the first coil generates a magnetic field.

30. The force measurement device of claim 16, further comprising:
a first adder;
a second adder; and
a signal processing unit;
wherein the first magnetic field sensor and the third magnetic field sensor are connected to the first adder so that the signal provided by these sensors are added;
wherein the second magnetic field sensor and the fourth magnetic field sensor are connected to the second adder so that the signal provided by these sensors are added; and
wherein the signal processing unit is connected to the first adder and to the second adder and configured to process the signals provided by the first and second adders in order to determine a force applied to a test object.
